(19) United States
(12) Patent Application Publication
(10) Pub. No.: US 2007/0275620 A1
(43) Pub. Date: Nov. 29, 2007

(54) Electro-Optic Fibre or Filament

(75) Inventors: Jacob M.J. Den Toonder, Helmond (NL); Johannes T.A. Wilderbeek, Eindhoven (NL); Martijn Krans, Den Bosch (NL); Michel P.B. Van Bruggen, Helmond (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/574,914

(22) PCT Filed: Sep. 13, 2005
(86) PCT No.: PCT/IB05/52988

§ 371 Date: Mar. 8, 2007

(30) Foreign Application Priority Data
Sep. 14, 2004 (EP) 0420383.2

(51) Int. Cl. H01L 27/32

(52) U.S. Cl. 442/181; 28/140; 427/111; 428/364

(57) ABSTRACT

An electro-optic fibre (4) or filament comprising: a first electrode (6); a second electrode (8); and an electro-optically active material (10) positioned at least partially between the first and second electrodes, the second electrode comprising a plurality of spaced apart segments (12) each segment having a length that is no more than a maximum length, and no less than a minimum length, extending at least partially along the length of the fibre or filament.

This invention relates to a fibre or filament, especially one that is suitable for inclusion in a fabric or garment having one or more indicator displays incorporated therein, and to a fabric or garment having one or more indicator displays incorporated therein.

Various methods of producing colour changing, or light emitting fabrics are known.

One known method and fabric is disclosed in US patent application No. US 2002/0187697 assigned to Visson IP LLC. The fabric disclosed therein is formed from first and second sets of fibres, each fibre having a longitudinal conductive element. The two sets of fibres form a matrix structure of junctions, and the structure further comprises an electro-optically active substance which coats at least partially the fibres of the first set. A voltage difference exists between the longitudinal conductive elements of the fibres of the first set, and those of the second set, where a fibre from each set meets a junction. The junction formed by a fibre of the first set crossing over with a fibre of the second sets activates the electro-optically active material and produces a display element.

A problem with existing methods and fabrics of this type is that the optical effect, which may be either a colour changing effect or a light emitting effect, occurs only at the junctions of the first and second sets of fibres. This area can be relatively small, and is largely determined by the cross section of the diameters of the fibres forming the first and second sets of fibres. The diameters are each typically in the range of 5 μm to 300 μm.

Another known fabric and method disclosed in International patent application No. WO 03/005775 attempts to overcome the problem of having a small area in which the optical effect occurs, by filling cells positioned between the fibres with an electro-optical substance.

A disadvantage of such fabrics and methods is that additional conductive layers enclosing the woven structure are needed.

It is an objection of the present invention to provide an electro-optic fibre or filament, and a fabric formed from such fibre or filament, that overcomes these problems.

According to a first aspect of the present invention there is provided an electro-optic fibre or filament comprising:
a first electrode;
a second electrode; and
an electro-optically active material positioned at least partially between the first and second electrodes, the second electrode comprising a plurality of spaced apart segments each segment having a length that is no more than a maximum length Lₘₐₓ, and no less than a minimum length Lₘᵢₙ, extending at least partially along the length of the fibre or filament.

According to a second aspect of the present invention there is provided a textile or fabric comprising a plurality of electro-optic fibres or filaments, each of the electro-optic fibres or filaments comprising:
a first electrode;
a second electrode; and
an electro-optically active material positioned at least partially between the first and second electrodes, the second electrode comprising a plurality of spaced apart segments, each segment having a length that is no more than a maximum length Lₘₐₓ, and no less than a minimum length Lₘᵢₙ, which segments extend at least partially along the length of the fibre, the textile or fabric further comprising a plurality of conductive fibres interwoven with the plurality of electro-optic fibres or filaments.

Because the plurality of conductive fibres are interwoven with the plurality of electro-optic fibres or filaments, each of the conductive fibres will make contact with an individual segment of at least one of the plurality of electro-optic fibres.

It is thus possible to locally address an individual segment forming part of one of the electro-optic fibres or filaments by creating a voltage difference between a conductive fibre that is in contact with the segment, and the first electrode of the electro-optic fibre.

The optical state of the electro-optically active material surrounded by the segment may be changed in response to the voltage difference applied between the conductive fibre and the electro-optic fibre. The change in optical state of the electro-optically active material in this portion of the electro-optic fibre may be such that the electro-optically active material emits light. The area of the fibre that emits light will be determined by the dimensions of the segment.

Preferably, the segments are physically and electrically isolated from one another.

The plurality of segments may each have substantially the same length, L, as one another or one, or more of the segments may have a length that is different to one or more of the other segments.

The segments are preferably spaced apart from one another by a distance d.

The conductive fibres are preferably spaced apart from one another by a distance I that is less than the length L of segments forming the plurality of electro-optic fibres or filaments.

When the length of the segments varies, the conductive fibres are preferably spaced apart by a distance I that is less than the minimum length Lₘᵢₙ of the segments.

The distance I between the conductive fibres may be substantially constant within the textile fabric. Alternatively, the distance between adjacent conductive fibres may vary between a maximum distance Iₘₐₓ and a minimum distance Iₘᵢₙ.

In such an embodiment, the maximum distance between adjacent conductive fibres Iₘₐₓ is preferably less than the minimum length Lₘᵢₙ of segments forming the second electrodes of the plurality of electro-optic fibres or filaments.

Advantageously, the textile or fabric according to the present invention further comprises a connector element adapted to contact a plurality of conductive fibres, and a plurality of first electrodes.

Preferably, the textile or fabric comprises a plurality of connector elements, spaced apart from one another by a distance λ that is greater than the length L of the segment.

In an embodiment of the invention where the length of the segments L varies, the contacting connectors are spaced apart by a distance λ that is greater than the maximum length L_{max of} the segments.

An electro-optic fibre or filament according to the present invention may either be substantially cylindrical, or may be substantially flat or “ribbon” like.

When the electro-optic fibre or filament is substantially cylindrical, the first electrode preferably comprises an inner electrode, and the second electrode preferably comprises an outer electrode.

When the electro-optic fibre or filament is substantially flat, the first electrode preferably comprises an inner electrode, and the second electrode preferably comprises a first outer electrode and a second outer electrode. The electro-optically active material further comprises a first layer positioned between the first electrode and the first outer electrode, and a second layer positioned between the first electrode and the second outer electrode.

Conveniently, the second electrode is transparent or translucent.

The electro-optically active material may be any convenient substance, the optical properties of which may be changed by an electrical stimulus.

Preferably, the electro-optically active material comprises an electro-luminescent material. Preferably, large band gap semiconductors are employed, such as II-VI compounds (e.g. ZnS and SrS, doped with for instance Mn, Cu, Eu, or Ce) and rare earth oxides and oxysulfides, and insulators.

Advantageously, the second electrode comprises a polymeric material. Non-limitative examples of organic electrode materials are conductive or semi-conductive oligomers or polymers, such as polyaniline derivatives, polypyrrole derivatives and thiophene derivatives, such as poly(3,4-ethylenedioxythiophene): PEDT or PEDOT.

Alternatively, the second electrode comprises inorganic materials such as indium tin oxide (ITO), indium zinc oxide or thin layers of gold, copper, silver, platinum and their derivatives.

The fibre or filament may comprise one or more additional layers such as a dielectric layer, spacer layer, protective or barrier layer, an outer coloured layer or alignment layers for liquid crystals. For instance, dielectric layers may advantageously be applied when the electro-optical material comprises an electroluminescent layer. Because of the high field strengths, any imperfection in the fibre or filament would have a destructive effect on the electroluminescent layer. Therefore, current limiting layers, i.e. insulators or dielectrics, are required on either side of the electroluminescent layer to produce a reliable device structure. The insulators limit the maximum effective current to the electroluminescent layer.

Optional partial or patterned spacer layers may be employed to establish a well-defined layer thickness for the electro-optical material.

Coloured coatings can provide aesthetic effects, whereas protective layers can for instance increase the mechanical strength of the fibre (e.g. to improve handling), or protect against harsh chemical or physical environments (e.g. washing conditions).

Alignment layers, such as rubbed polyimide layers or photo-alignment layers, can optionally be employed to induce a desired orientation of anisotropic electro-optic materials, such as liquid crystal based materials.

According to a third aspect of the present invention there is provided a method of fabricating an electro-optic fibre or filament, the electro-optic fibre or filament comprising a first electrode;
a second electrode; and an electro-optically active material positioned at least partially between the first and second electrodes, the second electrode comprising a plurality of spaced apart segments extending at least partially along the length of the fibre or filament, the method comprising the steps of:
a) surrounding the first electrode with an electro-optically active material;
b) applying a second electrode material to the electro-optically active material;
c) forming the second electrode into the plurality of spaced apart segments.

Preferred and advantageous features of the third aspect of the invention as set out in dependent claims 20 to 26.

According to a fourth aspect of the present invention there is provided a method of manufacturing a textile or fabric comprising the steps of interweaving a plurality of conductive fibres with a plurality of electro-optic fibres, each of the electro-optic fibres comprising
a first electrode;
a second electrode; and
an electro-optically active material positioned at least partially between the first and second electrodes, the second electrode comprising a plurality of spaced apart segments each segment having a length that is no more than a maximum length Lₘₐₓ, and no less than a minimum length Lₘᵢₙ, extending at least partially along the length of the fibre or filament.

The invention will now be described by way of example only with reference to the accompanying drawings in which:

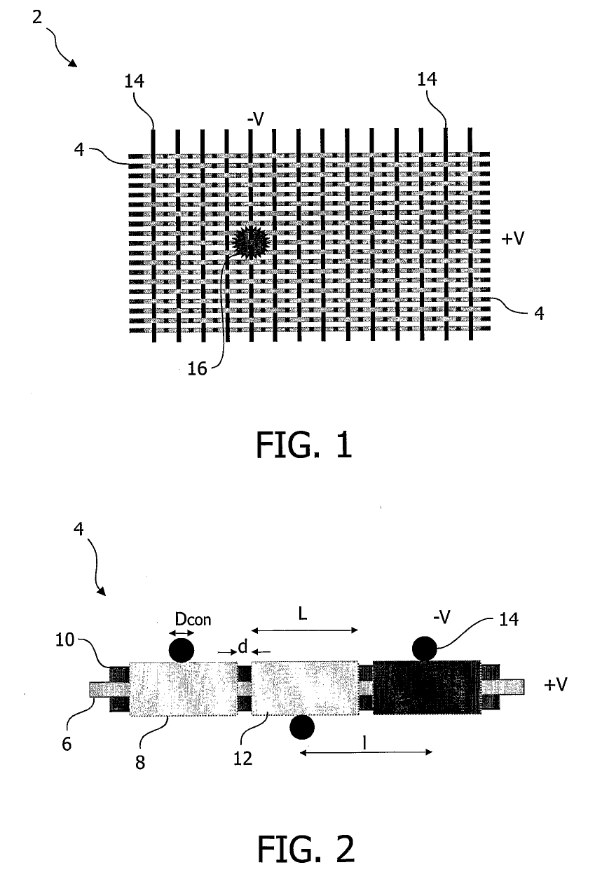

FIG. 1 is a schematic representation of a fabric according to the second aspect of the present invention;

FIG. 2 is a schematic representation of a fibre or filament according to the first aspect of the present invention forming part of the fabric of FIG. 1, and showing the position of conductive fibres;

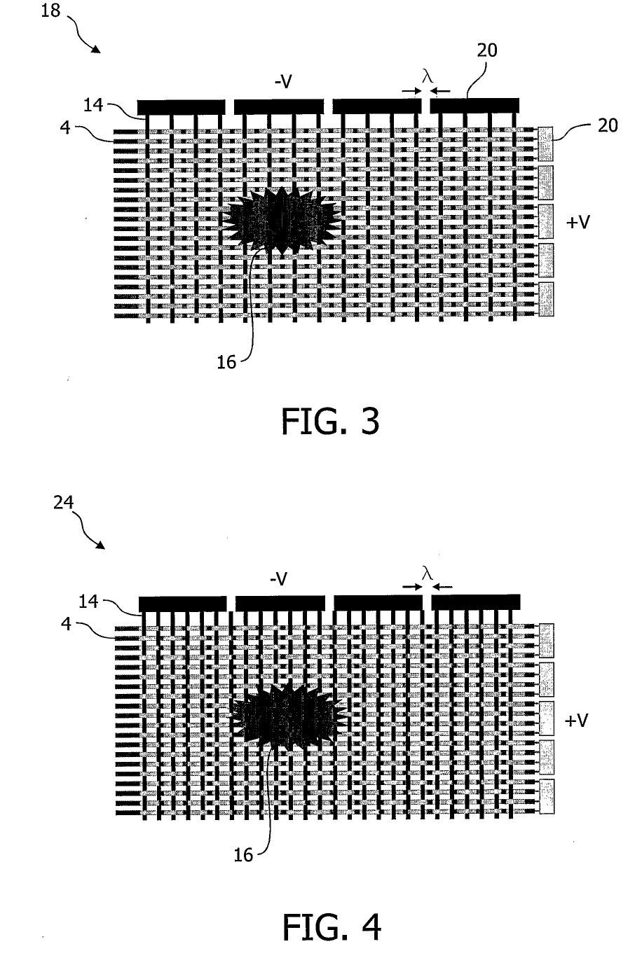

FIG. 3 is a schematic representation of a second embodiment of a fabric according to the second aspect of the present invention in which the fabric further comprises contacting connectors;

FIG. 4 is a schematic representation of a third embodiment of a fabric according to the second aspect of the present invention in which the distance between conductive fibres is smaller than the length of segments forming the second electrodes of the fibres or filaments according to the first aspect of the present invention forming the fabric;

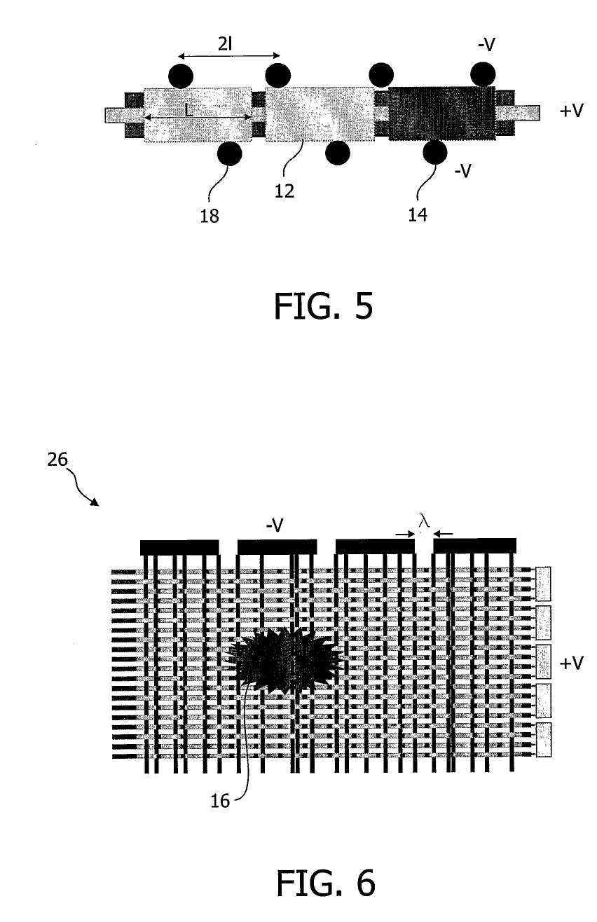

FIG. 5 is a schematic representation showing a fibre or filament according to the first aspect of the present invention forming part of the textile of FIG. 4, and showing the position of conductive fibres;

FIG. 6 is a schematic representation of a fourth embodiment of a fabric according to the second aspect of the present invention, in which the spacing between adjacent conductive fibres varies across the fabric;

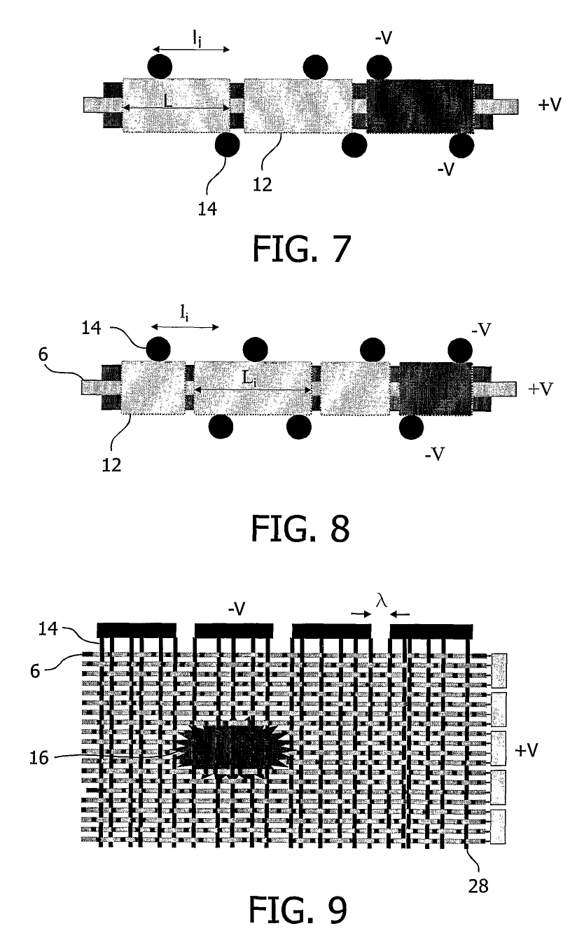

FIG. 7 is a schematic representation showing a fibre or filament according to the first aspect of the invention forming the textile of FIG. 6 and showing the positioning of the conductive fibres;

FIG. 8 is a schematic representation of a fibre or filament according to the first aspect of the invention used to form the fabric shown in FIG. 4, in which the length of segments forming the second electrodes of the electro-optic fibres or filaments varies within the fabric; and

FIG. 9 is a schematic representation of a fibre or filament used to form the fabric shown in FIG. 6, in which the distance between adjacent conductive fibres varies across the fabric, and the length of segments forming the second electrodes of the electro-optic fibres or filaments varies within the fabric.

Referring to FIGS. 1 and 2, a textile or fabric according to the second aspect of the present invention is designated generally by the reference numeral 2. The fabric 2 is formed from an electro-optic fibre according to the first aspect of the present invention designated generally by the reference numeral 4. The fibre 4 comprises a first electrode 6 in the form of a conductive core, and a second electrode 8. The fibre 4 further comprises an electro-optically active material positioned at least partially between the first electrode 6 and the second electrode 8. The electro-optically active material may be any substance, the optical properties of which can be changed by an electrical stimulus.

The second electrode 8 comprises a plurality of segments 12 that extend along the length of the fibre 4. Each of the segments 12 is physically and electrically separated from each other segment 12.

The segments 12 each comprise a transparent coating. The segments could also comprise translucent coatings or other types of coatings that allow light emitted within the fibre to be transmitted out of the fibre 4.

Adjacent segments 12 are separated from one other by distance d.

The fabric 2 is formed by interweaving a plurality of conductive fibres 14 with a plurality of electro-optic fibres 4. The conductive fibres each have a diameter D_{con}. When a voltage is applied between one conductive fibre 14 and a first electrode 6, a section of the fibre 4 enclosed by the segment 12 contacted by the conductive fibre 14, will undergo a change in optical properties. In other words the portion of the fibre 4 enclosed by the segment 12 will have a change of optical state. This portion will form a “pixel” 16.

By means of the invention therefore a locally addressable fabric is obtained, the “pixel size” of which is determined by the size of the segment 12 forming the electro-optic fibres 4. This is a significantly larger area than the area of contact between the conductive fibre 14 and electro-optic fibre 4.

In known fabrics comprising electro-optic fibres and conductive fibres, the optical effect, which may be either a colour changing effect or a light emitting effect, occurs only at the junctions of the electro-optic fibres and the conductive fibres. This area A can be relatively small, and is determined by
A=D_{con}·Dₑₒ

where A is the area comprising the optical effect, and D_{con} on and Dₑₒ are the diameter of the conductive and electro-optical fibres, respectively.

In the present invention however, the area A in which the change of optical state occurs, is determined by

provided
Lₘᵢₙ<Lᵢ<Lₘₐₓ

where A is the area in which the change of optical effect occurs, Dₑₒ is the diameter of the electro-optical fibre, Lᵢ is the length of an individual segment 12, as will be explained in more detail herein below, that may vary within the boundaries Lₘᵢₙ and Lₘₐₓ.

As preferably Lᵢ>D_{con}, the area A, will be significantly increased compared to the prior art, and its exact dimensions are largely determined by Lᵢ. Furthermore, the diameter of the conductive fibre 14 is not relevant to the dimensions of area A, provided that the physical and electrical contact between conductive fibre 14 and segment 12 is established.

Turning now to FIG. 3, a second embodiment of the fabric according to the second aspect of the present invention is designated generally by the reference numeral 18. Parts of the fabric 18 that correspond to parts of fabric 2 have been given corresponding reference numerals for ease of reference. The electro-optic fibres 4 used to form the fabric 18 are the same as those illustrated in FIG. 1.

The fabric 18 further comprises contacting connectors 20. Each connector element contacts more than one conductive fibre 14, and more than one first electrode 6. The connector elements are spaced apart from one another by a distance A. The “pixel size” of the fabric 18 is now determined by the number of conductive fibres 14 and first electrodes 6 contacted by each connecting element 20, whereas the intensity of the “pixel” 16 is determined by the total area of the segments 12 within the pixel 22.

The fabric 18 would be suitable for indicator type applications for which coarser resolutions are sufficient, as opposed to display applications, for example, where high resolutions are required.

In each of the embodiments illustrated in FIGS. 1 to 3, the conductive fibres 14 must be well aligned with the segments 12. This is because the spacing between adjacent conductive fibres 14 is substantially equivalent to the length of each segment 12 plus the distance d separating each segment 12.

Turning now to FIGS. 4 and 5, a further embodiment of a fabric according to the present invention is designated by the reference numeral 24. Parts of the fabric 24 that correspond to parts of fabric 2 have been given corresponding reference numerals for ease of reference.

The distance between individual conducting fibres 14 forming fabric 24 is arranged to be smaller than the length of each segment 12. This means that it is not necessary to align the conductive fibres 14 with the electro-optic fibres 4.

This in turn relaxes the tolerances in manufacturing the fabric 24. In such an embodiment, it is preferably that the connecting elements 20 are spaced sufficiently far apart from one another to avoid shorts which would lead to line faults. In other words A is arranged to be greater than L.

Turning now to FIGS. 6 and 7, a further embodiment of a fabric according to the second aspect of the present invention is designated generally by the reference numeral 26. Parts of the fabric 26 that correspond to parts of fabric 2 have been given corresponding reference numerals for ease of reference.

The conductive fibres 14 forming the fabric 26 are not required to be regularly spaced. There may be a spread in the distances between adjacent conductive fibres 18 so that a given space in between adjacent conductive fibres Iᵢ, is greater than Iₘᵢₙ and less than Iₘₐₓ, where Iₘₐₓ is less than L to ensure that a proper connection to all existing segments 12 takes place.

To ensure that the contacting connectors are spaced sufficiently far from each other to avoid shorts leading to line faults, the spacing between adjacent connecting elements 20 should be greater than the length of the segments 12.

Turning now to FIGS. 8 and 9, a further embodiment of a fabric or fibre according to the invention is shown. The fabric is designated by the reference numeral 28 and parts of the fabric and fibre corresponding to parts of the fabric and fibre illustrated in FIGS. 1 and 2 have been given corresponding reference numerals for ease of reference. The conductive fibres 14 need not be aligned with respect to the electro-optic fibres or filaments 4. The segments 12 of the electro-optic fibres 4 need not be the same size. The length of the segments 12 may vary within the boundaries: Lₘᵢₙ<Lᵢ<Lₘₐₓ, where Lᵢ is the length of an individual segment 12.

The conductive fibres 14 need not be aligned with respect to one another. Under these circumstances the following conditions apply:

1. the maximum distance between the conductive fibres 14, Iₘₐₓ, must be less than the minimum length of the segments 12 of the fibres 4, Lₘᵢₙ i.e., Iₘₐₓ is less than Lₘᵢₙ.

2. a “pixel” 16 is formed by several junctions between electro-optic fibres 4 and conductive fibres 14, as determined by the number of first electrodes 6, and conductive fibres 14 contacted by the connecting elements 20. The “pixel” 16 so formed is significantly larger than the mean distance between the conductive fibres 14 and the electro-optic fibres 4 respectively. In addition, it is preferable that the connecting elements 20 are spaced sufficiently far from each other to avoid shorts leading to line faults. In other words, the spacing between contacting connectors λ is greater than Lₘₐₓ.

Further, the electro-optic fibres 4 need not be at equidistant spacing.

The resulting fabric is one having relatively high manufacturing tolerances, since it is not longer necessary to accurately position the conducting fibres 14, the electro-optic fibres 4, or to accurately dimension the segments 12.

In addition, the resulting fabric will be more robust and flexible due to the discrete segments 12.

The material forming the segments 12 in any of the embodiments described hereinabove may be organic or inorganic. An example of an inorganic transparent conductive material is indium tin oxide (ITO), indium zinc oxide or thin semi-transparent layers of gold, copper, and their derivatives. Examples of conductive organic materials are conductive or semi-conductive oligomers or polymers, such as polyaniline derivatives, polypyrrole derivatives and thiophene derivatives, such as poly(3,4-ethylenedioxythiophene): PEDT or PEDOT.

If the segments 12 are to be formed from an organic material, the segments may be formed by initially applying a film of polymeric material as a continuous layer over an electro-optically active material. The film may be deposited using well-known techniques such as sputtering, evaporation, dip coating, fibre coating etc.

In addition, the film of the polymeric material may be applied discontinuous, at pre-determined intervals, thus inducing physical and electrical discontinuations in the resulting film.

The material may be patterned into segments 12 using lithographic techniques. Lithography characterises a number of methods for replicating a predetermined master pattern (e.g. using a mask) on a substrate. The replication of the pattern is generally effected by first coating the substrate with a radiation-sensitive polymer film (a resist) and then exposing the film to radiation in a pattern-wise manner. The radiation chemistry that results alters the physical or chemical properties of the exposed areas of the film such that they can be differentiated in a subsequent image development step. Most commonly, the solubility of the film is modified with the radiation chemistry either increasing the solubility of exposed areas (yielding a positive image of the mask after develop) or decreasing the solubility to yield a negative-tone image of the mask. This results in a patterned out second electrode formed into segments 12.

If the segments 12 are to be formed from a brittle conductive material such as ITO, use may be made of the brittle properties of the material to make a well defined crack pattern that defines the segments 12. In order to make a well defined crack pattern, the brittle material is applied to a more compliant substrate, and the substrate and film system is loaded in uniform uniaxial tension in the in-plane direction. This will cause cracks to appear in the brittle film in a direction perpendicular to the direction of tension. The distance between the cracks is fairly constant and is determined by the fracture properties of the film, the thickness of the film, the adhesion between the film and the substrate, the elastic/plastic properties of the film, and, particularly, the applied stress/strain.

This means that, when the first electrode 4 and electro-optic material 10 of the fibres 4 are more compliant than the ITO, a regular pattern of cracks perpendicular to the fibre direction 4 can be obtained by loading the fibre in tension, and longitudinal segments are formed. The distance between the cracks determines the length of the segments 12, and can be tuned by properly choosing materials and geometry, and by controlling the applied tension. To prevent closure of the cracks after removal of the tension, it is necessary for the electrode 6 to deform plastically during the loading, which can be controlled by proper material choice and by appropriate choice of the thickness/diameter of the electrode 6.

Where the second electrode is applied as a fluid coating, use may be made of fluid instability. It is known that a fluid film covering a cylindrical surface is unstable, and that such a fluid film will break up longitudinally into drops after a certain time. This instability is driven by the liquid surface tension. Drops with a certain periodicity over the length of the fibre will form, and the periodicity as well as the timescale in which the drops will form can be controlled by tuning the fluid properties (surface tension, viscosity), as well as by tuning the process conditions (coating speed, temperature). Curing of the fluid after the formation of the drops will lead to a segmented conductive coating.

Other techniques that could be used are microcontact printing or other soft lithography approaches. A pattern may be transferred to a substrate by microcontact printing with a patterned stamp using one of more suitable “inks” and a subsequent development step, thus transferring the printed pattern into the substrate material via etching processes. The result of the development process may be a positive or negative image of the stamp, depending on the type of inks that were used.

It is not necessary for the distance between conductive fibres 14 to be regular, as long as the mean distance between the fibres 14 is equal to or smaller than the length of the segment 12.

1. An electro-optic fibre (4) or filament comprising:
a first electrode (6);
a second electrode (8); and
an electro-optically active material (10) positioned at least partially between the first and second electrodes, the second electrode comprising a plurality of spaced apart segments (12) each segment having a length that is no more than a maximum length Lₘₐₓ, and no less than a minimum length Lₘᵢₙ, extending at least partially along the length of the fibre or filament.

2. An electro-optic fibre (4) or filament according to claim 1 wherein the segments (12) are electrically and physically isolated from one another.

3. An electro-optic fibre (4) or filament according to claim 1 wherein the segments (12) are spaced apart from one another by a distance d.

4. An electro-optic fibre (4) or filament according to claim 1 wherein the second electrode (8) is transparent.

5. An electro-optic fibre (4) or filament according to claim 1 wherein the first electrode (6) comprises an inner electrode, and the second electrode (8) comprises an outer electrode.

6. An electro-optic fibre (4) or filament according to claim 1 that is substantially cylindrical.

7. An electro-optic fibre (4) or filament according to claim 1 that is substantially flat.

8. An electro-optic fibre (4) or filament according to claim 7 wherein the first electrode (6) comprises an inner electrode, the second electrode (8) comprises a first outer electrode and a second outer electrode, and the electro-optically active material (10) comprises a first layer positioned between the first electrode and the first outer electrode, and a second layer positioned between the first electrode and the second outer electrode.

9. An electro-optic fibre (4) or filament according to claim 1 wherein the electro-optically active material (10) comprises an electro-luminescent material.

10. An electro-optic fibre (4) or filament according to claim 1 wherein the electro-optically active material (10) comprises large band gap semiconductors.

11. An electro-optic fibre (4) or filament according to claim 1 wherein the second electrode (8) comprises a polymeric material.

12. An electro-optic fibre (4) or filament according to claim 1 wherein the second electrode (8) comprises conductive or semi-conductive oligomers or polymers.

13. An electro-optic fibre (4) or filament according to claim 1 wherein the second electrode (8) comprises indium tin oxide.

14. A textile or fabric (2) comprising an electro-optic fibre or filament according to claim 1 and further comprising a plurality of conductive fibres (14) interwoven with the plurality of electro-optic fibres or filaments.

15. A textile or fabric (2) according to claim 14 wherein the plurality of conductive fibres (14) are spaced apart from one another by a distance 1 that is less than the minimum length Lₘᵢₙ of the segments.

16. A textile or fabric (2) according to claim 12 further comprising a connector element (20), which connector element contacts a plurality of conductive fibres (14), and a plurality of first electrodes (6).

17. A textile or fabric (2) according to claim 16 comprising a plurality of connector elements (20), spaced apart from one another by a distance λ, each of which connector elements contacts a plurality of conductive fibres (14), and a plurality of first electrodes (6).

18. A textile or fabric (2) according to claim 17 wherein the plurality of connector elements (20) are spaced apart from one another by a distance λ that is more than the maximum length Lₘₐₓ of the segments.

19. A method of fabricating an electro-optic fibre (4) or filament, the electro-optic fibre or filament comprising a first electrode (6);
a second electrode (8); and an electro-optically active material (10) positioned at least partially between the first and second electrodes, the second electrode comprising a plurality of spaced apart segments (12) extending at least partially along the length of the fibre or filament, the method comprising the steps of:
a) surrounding the first electrode with an electro-optically active material;
b) applying a second electrode material to the electro-optically active material;
c) forming the second electrode into the plurality of spaced apart segments.

20. A method according to claim 19 wherein the second electrode material is organic and step b) comprises one of: sputtering; evaporation; dip coating or fluid coating.

21. A method according to claim 20 wherein the second electrode material is applied discontinuously.

22. A method according to claim 20 wherein step c) comprises the sub-steps of
d) applying a resist to the second electrode (8) in the form of a substantially continuous film;
e) illuminating the resist through a mask to locally alter the physical or chemical properties of the exposed areas of the film to leave uncovered areas of the electrode;
f) etching the electrode material; and
g) removing the resist.

23. A method according to claim 19 wherein the second electrode material comprises indium tin oxide (ITO).

24. A method according to claim 19 comprising the initial step of forming the first electrode (6) from a plastically deformable material, and step c) comprises the sub-step of:
h) loading the electro-optic fibre (4) or filament in tension to form the plurality of segments (12).

25. A method according to claim 19 wherein the second electrode material comprises a fluid.

26. A method of manufacturing a fabric or textile or fabric (2) comprising the steps of interweaving a plurality of conductive fibres (14) with a plurality of electro-optic fibres (4), each of the electro-optic fibres comprising
a first electrode (6);
a second electrode (8); and
an electro-optically active material (10) positioned at least partially between the first and second electrodes, the second electrode comprising a plurality of spaced apart segments (12) each segment having a length that is no more than a maximum length Lₘₐₓ, and no less than a minimum length Lₘᵢₙ, extending at least partially along the length of the fibre or filament.

27. A fibre (4) or filament substantially as hereinbefore described with reference to the accompanying drawings.

28. A method substantially as hereinbefore described with reference to the accompanying drawings.

29. A fabric (2) or textile substantially as hereinbefore described with reference to the accompanying drawings.
